(19) United States
(12) Patent Application Publication
(10) Pub. No.: US 2017/0029932 A1
(43) Pub. Date: Feb. 2, 2017

(54) SLIDING MEMBER AND PRODUCTION METHOD THEREOF

(71) Applicants: TOYOTA JIDOSHA KABUSHIKI KAISHA, Toyota-shi (JP); NATIONAL UNIVERSITY CORPORATION NAGOYA UNIVERSITY, Nagoya-shi (JP)

(72) Inventors: Kazuyoshi MANABE, Toyota-shi (JP); Noritsugu UMEHARA, Nagoya-shi (JP); Hiroyuki KOUSAKA, Nagoya-shi (JP); Takafumi HATTORI, Nagoya-shi (JP)

(73) Assignees: TOYOTA JIDOSHA KABUSHIKI KAISHA, Toyota-shi (JP); NATIONAL UNIVERSITY CORPORATION NAGOYA UNIVERSITY, Nagoya-shi (JP)

(21) Appl. No.: 15/220,680

(22) Filed: Jul. 27, 2016

(30) Foreign Application Priority Data
Jul. 27, 2015 (JP) 2015-148058

(51) Int. Cl. C23C 14/22; C23C 14/06

(52) U.S. Cl. CPC C23C 14/22; C23C 14/0605

(57) ABSTRACT

A sliding member is capable of moving relative to a counterpart and includes a substrate and an amorphous carbon film which is provided on the substrate. The amorphous carbon film has a nitrogen content of 2 at % to 11 at % and a surface hardness in a range of 25 GPa to 80 GPa.

### INCORPORATION BY REFERENCE

The disclosure of Japanese Patent Application No. 2015-148058 filed on Jul. 27, 2015 including the specification, drawings and abstract is incorporated herein by reference in its entirety.

### BACKGROUND OF THE INVENTION

1. Field of the Invention

The invention relates to a sliding member, which is capable of moving relative to a counterpart, in which an amorphous carbon film containing nitrogen is formed on a sliding surface. More particularly, to a sliding member which allows the surface of an amorphous carbon film to act as a sliding surface, and is for appropriate sliding in an environment of a lubricant being on the sliding surface, and a production method thereof.

2. Description of Related Art

Tribology has an important role in the basic industries of Japan, such as the automotive industry. For example, in the automotive industry, for global environmental protection, various efforts are currently being made to reduce carbon dioxide emissions from vehicles. As an example, the development of a power source with high energy efficiency, such as a hybrid system, is well known. However, for the purpose of a further reduction in fuel consumption, as well as the development of a power source, a reduction in energy transmission losses caused by friction in an engine or a driving system is an important issue.

Amorphous carbon materials (DLC) are receiving attention as novel tribological materials for coating the sliding surface of a sliding member made of structural steel or high alloy steel in order to achieve a reduction in the coefficient of friction of the sliding member in a power system device and improvement in wear resistance.

As an example of a production method of a sliding member which uses such an amorphous carbon material, for example, Japanese Patent Application Publication No. 2013-57093 (JP 2013-57093 A) proposes a production method of a sliding member in which an amorphous carbon film containing nitrogen is formed on the surface of a substrate. In this production method, an electron beam is emitted toward a carbon target to form a plurality of protrusions on the surface of the amorphous carbon film while a nitrogen ion beam is emitted toward the surface of the substrate such that the amorphous carbon film is formed while carbon particles vaporized from the carbon target are deposited on the surface of the substrate.

Accordingly, a plurality of protrusions are formed on the surface of the amorphous carbon film of the obtained sliding member, and the protrusions are softer than the surface of the amorphous carbon film excluding the protrusions. On the surface of the amorphous carbon film, the hardness of each protrusion is 12 GPa or less, and the hardness of the remaining surface is in a range of 14 GPa to 30 GPa. As described above, by providing the soft protrusions on the surface of the amorphous carbon film, the frictional characteristics of the sliding member can be improved in a non-lubrication state.

However, in a case where the sliding member described in JP 2013-57093 A is used in a high-load environment in which a lubricant is present, the formation of an oil film on a sliding surface may be impeded by the protrusions formed on the sliding surface. As a result, the wear amount of the sliding member increases during sliding, and there is concern that the coefficient of friction of the sliding member may increase.

Furthermore, since the protrusions are relatively large carbon particles (droplets) which are adhered during the film formation and come from the carbon target, soft parts are present in the amorphous carbon film even after the protrusions wear out after sliding. As a result, in a case where the sliding member is allowed to slide in a high-load environment, the wear amount of the sliding member increases even in an environment in which a lubricant is present.

### SUMMARY OF THE INVENTION

The invention provides a sliding member, which is capable of moving relative to a counterpart, in which the wear amount and the coefficient of friction of an amorphous carbon film formed on the sliding surface of the sliding member are able to be reduced even when the sliding member is allowed to slide under a high-load condition in which a lubricant is present, and a production method thereof.

A first aspect of the invention relates to a production method of a sliding member, which is capable of moving relative to a counterpart, which includes a nitrogen-containing amorphous carbon film formed on a surface of a substrate, allows a surface of the amorphous carbon film to act as a sliding surface, and is used in an environment in which a lubricant is present on the sliding surface. In the production method, the nitrogen-containing amorphous carbon film is formed by causing carbon to be deposited on the surface of the substrate through a filtered arc deposition method while emitting a nitrogen ion beam toward the surface of the substrate so as to cause a nitrogen content of the amorphous carbon film to be 2 at % to 11 at %.

According to the invention, carbon can be deposited on the surface of the substrate while coarse carbon particles are separated by deflected magnetic fields generated in a filtered arc deposition method (FAD method). Accordingly, an amorphous carbon film in which a smooth surface (sliding surface) is formed on the surface of the substrate without droplets can be obtained. In addition, the amorphous carbon film formed from carbon in the form of a plasma through carbon ion beam deposition is a harder film than that formed according to the method described in, for example, JP 2013-57093 A, and the film contains nitrogen in a proportion of 2 at % to 11 at %.

When the sliding member in which the amorphous carbon film is formed is allowed to slide, nitrogen in the surface of the amorphous carbon film as the sliding surface is released, and a graphite-like structural transition layer is formed on the sliding surface. Accordingly, even when the sliding member is allowed to slide in a high-load environment in which a lubricant is present, the coefficient of friction of the sliding member is reduced by the structural transition layer.

Particularly, in the amorphous carbon film, the underlayer of the structural transition layer formed during sliding is a hard layer which is harder than that in the related art. Therefore, there is a great difference in hardness between the structural transition layer and the hard layer. Accordingly, an adaptive effect of the structural transition layer is more significantly exhibited during sliding, and the sliding member exhibits a low coefficient of friction and can be provided with increased wear resistance.

Here, in a case where the nitrogen content of the amorphous carbon film is less than 2 at %, the amount of nitrogen released during sliding is low, and it is difficult to form the above-described structural transition layer. Therefore, a reduction in the coefficient of friction of the sliding member cannot be sufficiently achieved.

In addition, it is difficult to form an amorphous carbon film having a nitrogen content of more than 11 at %. Even if such an amorphous carbon film is formed, the hardness of the amorphous carbon film is low, and thus the adaptive effect of the structural transition layer exhibited due to the difference in hardness between the structural transition layer and the hard layer cannot be sufficiently exhibited.

The forming of the amorphous carbon film may be performed so as to cause the nitrogen content to be 10 at % to 11 at %. As is apparent from Examples made by the inventors, which will be described later, by causing the nitrogen content of the amorphous carbon film to be 10 at % to 11 at %, a reduction in the wear amount and a reduction in the coefficient of friction described above can be more reliably achieved.

A second aspect of the present invention relates to a sliding member which is capable of moving relative to a counterpart, comprising: a substrate; and an amorphous carbon film which is provided on the substrate, and has a nitrogen content of 2 at % to 11 at % and a surface hardness in a range of 25 GPa to 80 GPa.

In the sliding member according to the invention, when the sliding member is allowed to slide, nitrogen in the surface of the amorphous carbon film as the sliding surface is released, and a graphite-like structural transition layer is formed on the sliding surface. Accordingly, even when the sliding member is allowed to slide in a high-load environment in which a lubricant is present, the coefficient of friction of the sliding member is reduced by the structural transition layer formed on the sliding surface.

Particularly, in the amorphous carbon film, the underlayer of the structural transition layer formed during sliding is a hard layer which having a hardness of 25 GPa to 80 GPa. Therefore, there is a great difference in hardness between the structural transition layer and the hard layer. Accordingly, an adaptive effect of the structural transition layer is more significantly exhibited during sliding, and the sliding member exhibits a low coefficient of friction and can be provided with increased wear resistance.

Here, in an amorphous carbon film having a hardness of lower than 25 GPa, no adaptive effect caused by the difference in hardness described above can be expected. In addition, it is difficult to form an amorphous carbon film having a hardness of higher than 80 GPa.

Here, the description “the surface hardness of the amorphous carbon film is in a range of 25 GPa to 80 GPa” in the invention means that the hardness at any point on the surface of the amorphous carbon film is in a range of 25 GPa to 80 GPa.

The nitrogen content may be 10 at % to 11 at %. As is apparent from Examples made by the inventors, which will be described later, by causing the nitrogen content of the amorphous carbon film to be 10 at % to 11 at %, a reduction in the wear amount and a reduction in the coefficient of friction described above can be more reliably achieved.

According to the invention, even when the sliding member is allowed to slide under a high-load condition in which a lubricant is present, the wear amount and the coefficient of friction of the amorphous carbon film formed on the sliding surface of the sliding member can be reduced. The sliding member of the present invention may be a stationary member (a non-movable member) which includes the amorphous carbon film of the present invention, and on which a movable member slides.

### BRIEF DESCRIPTION OF THE DRAWINGS

Features, advantages, and technical and industrial significance of exemplary embodiments of the invention will be described below with reference to the accompanying drawings, in which like numerals denote like elements, and wherein:

FIG. 1 is a schematic view of a production apparatus for producing a sliding member according to an embodiment of the invention;

FIG. 2A shows a state of an amorphous carbon film of the sliding member before sliding;

FIG. 2B shows a state of the amorphous carbon film of the sliding member during sliding;

FIG. 3 shows the relationship between the nitrogen contents of the amorphous carbon films of the sliding members according to Examples 2 to 6, Comparative Example 1, and Reference Example 1 and the hardness of the amorphous carbon films thereof;

FIG. 4A is a schematic side view illustrating a ball-on-disk friction and wear tester;

FIG. 4B is a top view of FIG. 4A;

FIG. 5A shows the coefficients of friction of the sliding members (ball specimens) according to Examples 1 to 6 and Comparative Examples 1 and 2 in 3000 cycles of friction;

FIG. 5B shows the specific wear amounts of the sliding members (ball specimens) according to Examples 1 to 6 and Comparative Examples 1 and 2 after a ball-on-disk friction and wear test;

FIG. 6 shows changes in the coefficients of friction of the sliding members (ball specimens) according to Example 4 and Comparative Examples 1 to 3;

FIG. 7A shows the coefficients of friction of the sliding members (ball specimens) according to Example 4 and Comparative Example 1 in 3000 cycles of friction;

FIG. 7B shows the specific wear amounts of the sliding members (ball specimens) according to Example 4 and Comparative Example 1 after the ball-on-disk friction and wear test;

FIG. 8A shows the sliding surface of the sliding member (disk specimen) according to Comparative Example 1 after the ball-on-disk friction and wear test;

FIG. 8B shows the sliding surface of the sliding member (disk specimen) according to Example 4 after the ball-on-disk friction and wear test after sliding;

FIG. 9 is a schematic side view illustrating a block-on-ring friction and wear tester;

FIG. 10 shows changes in the coefficients of friction of the sliding members (block specimens) according to Example 4 and Comparative Example 2 during a block-on-ring friction and wear test;

FIG. 11A shows the sliding surface of the sliding member (block specimen) according to Comparative Example 2 after the block-on-ring friction and wear test; and

FIG. 11B shows the sliding surface of the sliding member (block specimen) according to Example 4 after the block-on-ring friction and wear test.

### DETAILED DESCRIPTION OF EMBODIMENTS

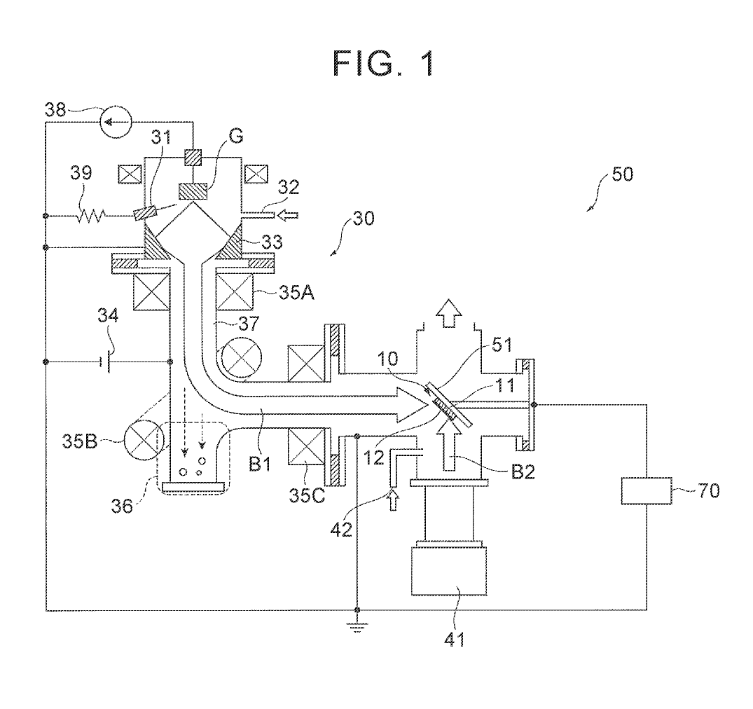

A sliding member according to an embodiment of the invention and a production method thereof will be described below. FIG. 1 is a schematic view of a production apparatus 50 for producing the sliding member according to the embodiment of the invention.

A sliding member 10 produced in this embodiment is a sliding member in which an amorphous carbon film (amorphous carbon nitride film, hereinafter referred to as CNx film) 12 containing nitrogen is formed on the surface of a substrate 11. The sliding member 10 slides in an environment in which a lubricant is present on the surface of the CNx film 12 as a sliding surface.

In the production method of the sliding member 10 according to this embodiment, carbon is deposited on the surface of the substrate 11 by a carbon ion beam B1 generated through a filtered arc deposition method while a nitrogen ion beam B2 is emitted toward the surface of the substrate 11 such that the nitrogen content of the CNx film 12 reaches 2 at % to 11 at %. Accordingly, the CNx film 12 is formed on the surface of the substrate 11.

As illustrated in FIG. 1, the production apparatus 50 used in this embodiment is a dynamic mixing film forming apparatus in which a T-shaped filtered arc deposition (FAD) film forming apparatus 30, which is generally used, and a microwave ion source 41 are combined.

Hereinafter, the production method of the sliding member 10 will be described. First, the substrate 11 of the sliding member 10 is prepared. Examples of the material of the substrate 11 include substrates made of steel, cast iron, aluminum, polymer resins, and silicon. The material is not particularly limited as long as the material has quality and surface hardness that ensure the adhesion to the CNx film during sliding.

An intermediate layer made of silicon (Si) may also be provided on the surface of the substrate 11 before the formation of the CNx film in order to improve the adhesion between the substrate 11 and the CNx film 12, and instead of silicon, chromium (Cr), titanium (Ti), or tungsten (W) may also be used.

Next, the CNx film 12 is formed on the surface of the substrate 11 using the production apparatus 50. First, a carbon target G which acts as a cathode is disposed at a position that faces an anode 33 of the film forming apparatus 30. The substrate 11 on which the CNx film 12 is to be formed is disposed on a stage 51.

Next, an arc discharge is generated at the carbon target G by a power supply unit 38 via a trigger resistance 39 while supplying argon gas from a first gas supply port 32. At this time, a plasma is generated due to the arc discharge such that carbon in the carbon target G is ionized.

Magnetic fields and electric fields generated by electromagnetic coils 35A to 35C and a power supply 34, which are disposed on the outside of a T-shaped duct 37, are applied to the obtained carbon ion beam B1 such that carbon ions are transported to the substrate 11 via the duct 37. At this time, a negative bias voltage is applied to the substrate 11 disposed on the stage 51 by a power supply 70. Accordingly, carbon ion beam deposition is performed on the substrate 11 through the filtered arc deposition method.

On the other hand, when carbon ion beam deposition is performed on the substrate 11, nitrogen gas is supplied to the production apparatus 50 from a second gas supply port 42 and the nitrogen ion beam B2 is emitted toward the surface of the formed substrate 11 using the microwave ion source 41. Accordingly, the CNx film 12 in which amorphous carbon is doped with nitrogen can be simply formed on the surface of the substrate 11. Here, by controlling the partial pressure of nitrogen introduced into the production apparatus 50, the nitrogen content of the CNx film 12 can be 2 at % to 11 at %.

Although not illustrated, in this embodiment, in order to form a more homogenous CNx film 12, a rotating mechanism is provided in the stage, and rotation of a motor connected to the rotating mechanism is transmitted to the substrate 11 which is supported by a carbon bearing via a spring.

In this embodiment, coarse carbon particles that come from the carbon target G generated during the arc discharge are separated by deflected magnetic fields generated in the duct 37 by the electromagnetic coils 35A to 35C so as to be collected in a droplet collecting portion 36 of the T-shaped duct 37 (μ-TFAD method). Accordingly, a smooth CNx film 12 which does not contain coarse particles (droplets) is formed on the surface of the substrate 11.

In addition, the formed CNx film 12 becomes a hydrogen-free hard film in which the ratio of sp³ bonds is high. Specifically, regardless of whether or not the nitrogen content of the CNx film 12 is 2 at % to 11 at %, the film density of the CNx film is in a range of 2.3 g/cm³ to 3.5 g/cm³ when the surface hardness of the CNx film is in a range of 25 GPa to 80 GPa.

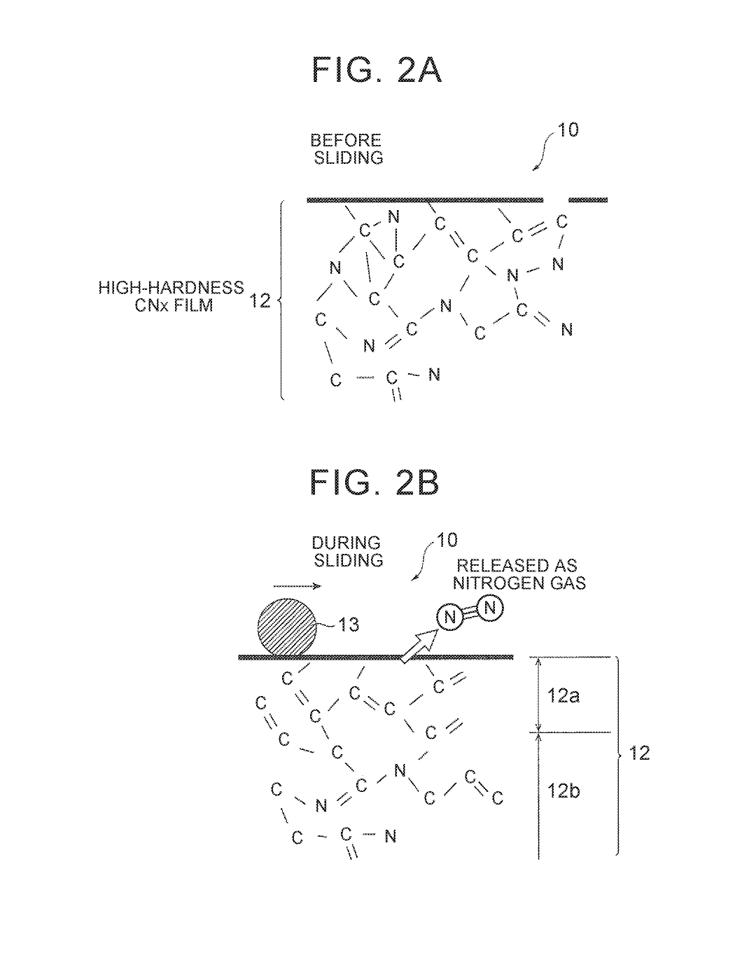

As described above, in this embodiment, deposition of carbon by the carbon ion beam (filtered arc plasma beam) B1 through the filtered arc deposition method and emission of the nitrogen ion beam B2 using the microwave ion source 41 are simultaneously performed on the substrate 11 disposed on the stage 51. Accordingly, as illustrated in FIG. 2A, the high-hardness CNx film 12 which has a smooth surface without droplets and contains nitrogen is formed.

Here, as illustrated in FIG. 2B, when the sliding member 10 provided with the CNx film 12 is allowed to slide, nitrogen in the surface of the CNx film 12 as the sliding surface is released, and a graphite-like structural transition layer 12a (with a layer thickness of 10 nm to 20 nm) is formed on the sliding surface.

Specifically, in a process of forming the structural transition layer 12a, energy needed to break the bond of each element included in the CNx film 12 is given by friction with an opponent member 13. Atoms which are not bonded as the bond is broken rebond repeatedly. Accordingly, nitrogen atoms become nitrogen gas and are released toward the outside from the CNx film 12, and carbon forms a C═C bond (carbon-carbon double bond) and remains in the CNx film 12.

As a result, even when the sliding member 10 is allowed to slide in a high-load environment in which a lubricant is present, since the graphite-like structural transition layer 12a is formed on the sliding surface, the structural transition layer 12a becomes an adaptive layer and the coefficient of friction of the sliding member 10 is reduced.

Moreover, in the CNx film 12, the underlayer of the structural transition layer 12a formed during sliding is a hard layer (underlayer) 12b which is harder than the CNx film formed in the above-described film forming method (specifically, has a hardness of 25 GPa to 80 GPa). Therefore, there is a great difference in hardness between the structural transition layer 12a and the hard layer 12b. As a result, an adaptive effect of the structural transition layer 12a is more significantly exhibited during sliding, and the sliding member 10 exhibits a low coefficient of friction and can be provided with increased wear resistance.

Here, in a case where the nitrogen content of the CNx film 12 is less than 2 at %, the amount of nitrogen released during sliding is low, and it is difficult to form the above-described structural transition layer 12a. Therefore, a reduction in the coefficient of friction of the sliding member 10 cannot be sufficiently achieved. In addition, it is difficult to form a CNx film having a nitrogen content of more than 11 at %. Even if such a CNx film is formed, the adaptive effect of the structural transition layer 12a exhibited due to the difference in hardness between the structural transition layer 12a and the hard layer 13b cannot be sufficiently exhibited.

Furthermore, in an amorphous carbon film having a hardness of lower than 25 GPa, the adaptive effect caused by the difference in hardness described above cannot be expected. In addition, it is difficult to form an amorphous carbon film having a hardness of higher than 80 GPa.

Particularly in a case where the nitrogen content of the CNx film 12 is 10 at % to 11 at % as in this embodiment, a reduction in wear amount and a reduction in the coefficient of friction can be more reliably achieved.

Hereinafter, Examples of the invention will be described.

### EXAMPLE 1

<Production of Sliding member> Using a dynamic mixing method in which a filtered arc plasma beam method (FAD method) and a nitrogen ion beam emission using a microwave ion source were combined, a nitrogen-containing amorphous carbon film (CNx film) of a substrate was formed. During film formation, the same film forming apparatus as that of the film forming apparatus illustrated in FIG. 1 described above was used.

First, as the substrate, a substrate (SUJ2 in JIS standards) corresponding to the shape of a specimen, which will be described later, was prepared. The substrate and a carbon target were disposed in a vacuum chamber, and the air in the vacuum chamber was evacuated by a turbomolecular pump to cause the inside of the chamber to be at 2.0 to 4.0×10⁻³ Pa. In addition, cooling water at 20° C. was circulated in a stage on which the substrate is provided such that the temperature of the substrate is maintained at a constant level.

Next, a nitrogen ion beam generation source was adjusted so that the flow rate of nitrogen gas introduced into a nitrogen ion generation source was 0.44 sccm, the partial pressure thereof was 3.07×10⁻² Pa, the accelerating voltage of assist nitrogen ions was an accelerating voltage of −100V (48 mA), and the microwave output of nitrogen assist ions was 142 W (a reflection output of 55 W). The nitrogen ion beam in the adjusted state was emitted toward the surface of the substrate, and argon gas was allowed to flow at 8 sccm, an arc discharge was generated at the carbon target under the conditions of an applied voltage of −100 V and an applied current of 30 A, and a carbon ion beam generated from carbon of the carbon target ionized by plasma was emitted toward the surface of the substrate to which a bias voltage of −100 V was applied, for 10 minutes. Accordingly, a CNx film having a thickness of 0.5 μm and a nitrogen content of 2 at % was formed on the surface of the substrate.

### EXAMPLE 2

As in Example 1, a sliding member was produced. The difference from Example 1 is that the nitrogen content of a CNx film was set to 4 at % as shown in Table 1 by changing the partial pressure of nitrogen gas.

### EXAMPLE 3

As in Example 1, a sliding member was produced. The difference from Example 1 is that the nitrogen content of a CNx film was set to 5 at % as shown in Table 1 by changing the partial pressure of nitrogen gas.

### EXAMPLE 4

As in Example 1, a sliding member was produced. The difference from Example 1 is that the nitrogen content of a CNx film was set to 8 at % as shown in Table 1 by changing the partial pressure of nitrogen gas.

### EXAMPLE 5

As in Example 1, a sliding member was produced. The difference from Example 1 is that the nitrogen content of a CNx film was set to 10 at % as shown in Table 1 by changing the partial pressure of nitrogen gas.

### EXAMPLE 6

As in Example 1, a sliding member was produced. The difference from Example 1 is that the nitrogen content of a CNx film was set to 11 at % as shown in Table 1 by changing the partial pressure of nitrogen gas.

### Comparative Example 1

As in Example 1, a sliding member was produced. The difference from Example 1 is that a CNx film was formed by an ion beam assisted deposition method (IBAD method) described in JP 2013-57093 A by setting the nitrogen content of the CNx film to 7.4 at % as shown in Table 1.

Specifically, a nitrogen ion beam was emitted toward the surface of a substrate, and an electron beam which is adjusted to cause the output of the electron beam for electron beam deposition to be a voltage of 10 kV was emitted toward a carbon target to melt and vaporize a portion of the carbon target such that the vaporized portion of the carbon target was deposited on the surface of the substrate irradiated with the nitrogen ion beam. In addition, in Comparative Example 1, it is difficult to control the nitrogen content, and the nitrogen content was at a constant level.

### Comparative Example 2

A sliding member (manufactured by NIPPON ITF, INC.) in which an amorphous carbon film (DLC film) that did not contain nitrogen but contained hydrogen was formed on the surface of a substrate through a PVD method was prepared.

### Comparative Example 3

As in Example 1, a sliding member was produced. The difference from Example 1 is that an amorphous carbon film (DLC film) which did not contain nitrogen was formed through an arc ion plating method (AIP method) as shown in Table 1.

### Reference Example 1

As in Example 1, a sliding member was produced. The difference from Example 1 is that a nitrogen ion beam was not emitted, and an amorphous carbon film (DLC film) in which the nitrogen content of the surface of a substrate was 0 at %, that is, nitrogen was not contained, was formed.

TABLE 1

| | | Nitrogen | Coefficient | Specific wear |
|---|---|---|---|---|
| | Film forming | content | of | amount (×10⁻⁸ |
| | method | (at %) | friction | mm³/Nm) |
| Example 1 | FAD method | 2 | 0.06 | 1.13 |
| Example 2 | FAD method | 4 | 0.07 | 2.08 |
| Example 3 | FAD method | 5 | 0.08 | 3.38 |
| Example 4 | FAD method | 8 | 0.11 | 0.36 |
| Example 5 | FAD method | 10 | 0.08 | 0.44 |
| Example 6 | FAD method | 11 | 0.05 | 0.20 |
| Comparative | IB AD method | 7.4 | 0.14 | 6.90 |
| Example 1 | | | | |
| Comparative | PVD method | 0 | 0.15 | 7.07 |
| Example 2 | | | | |
| Comparative | AIP method | 0 | — | — |
| Example 3 | | | | |
| Reference | FAD method | 0 | — | — |
| Example 1 | | | | |

Hardness Test

The hardness of the CNx films of the sliding members according to Examples 2 to 6 and Comparative Example 1 and the DLC film according to Reference Example 1 were measured. Specifically, a load displacement curve in a case where the indentation hardness of the surfaces thereof were measured by an AFM nanoindenter manufactured by Hysitron, Inc., a projection area of an indentation scar due to plastic deformation was calculated from the load displacement curve, and the hardness was calculated by dividing the maximum indentation load by the projection area of the indentation scar.

[Result 1] From the result, as described in Reference Example 1 and Examples 2 to 6, the hardness of the film had decreased as the nitrogen content had increased. However, compared to the CNx film obtained through the IBAD method as in Comparative Example 1, it can be seen that the hardness had increased about five times at the same nitrogen content.

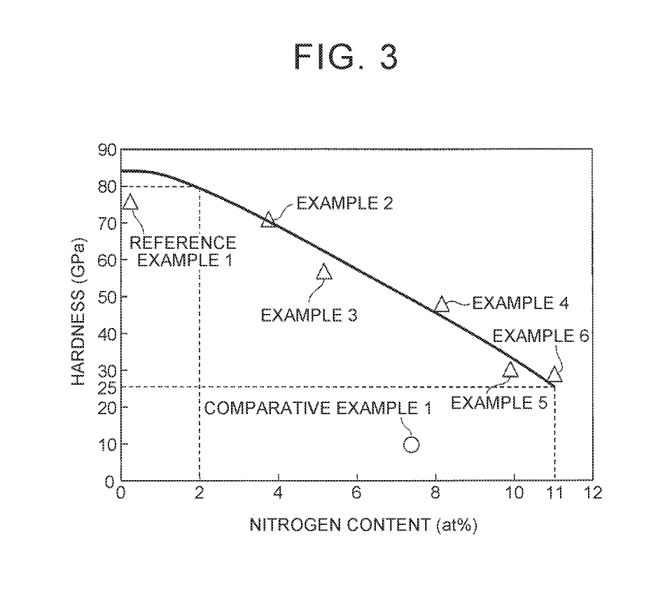

In addition, from the results of Reference Example 1 and Examples 2 to 6, it could be seen that when the CNx films having a nitrogen content of 2 at % to 11 at % were formed, the CNx films having a hardness of about 25 GPa to 80 GPa could be formed (see FIG. 3).

Ball-on-Disk Friction and Wear Test 1

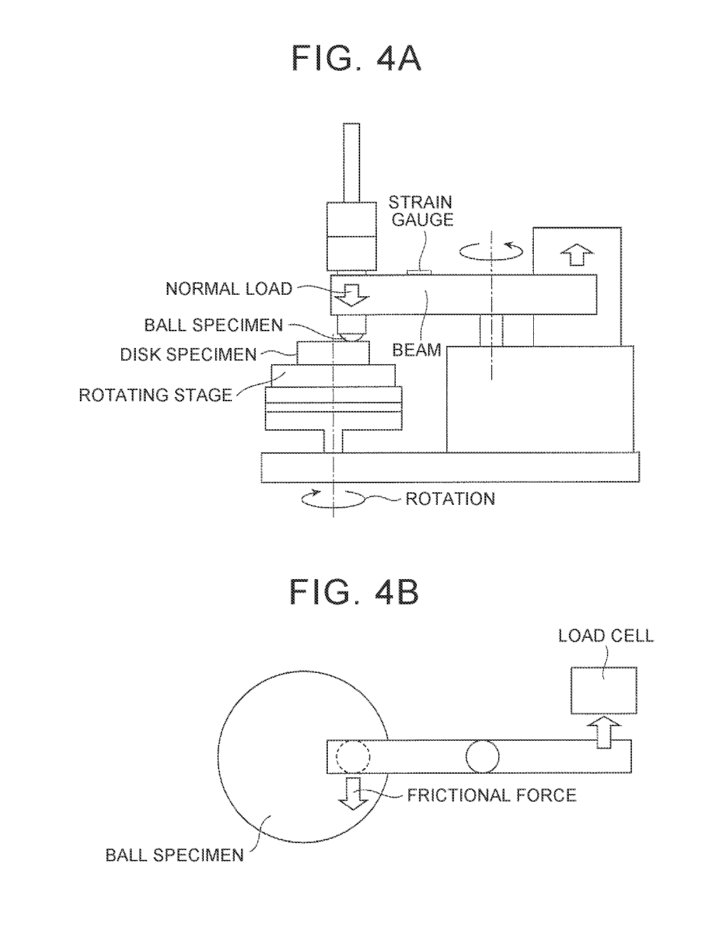

A ball-on-disk friction and wear test was conducted by using a tester illustrated in FIGS. 4A and 4B. Ball specimens as the sliding members according to Examples 1 to 6 and Comparative Examples 1 and 2 were prepared. Specifically, the CNx films and DLC films corresponding to Examples 1 to 6 and Comparative Examples 1 and 2 were formed on SUJ 2 (JIS standards) spherical bodies having a diameter of 8 mm. An SUJ 2 disk specimen was prepared as an opponent member.

Next, as illustrated in FIGS. 4A and 4B, the ball specimen fixed to a ball holder was fixed to a beam having a strain gauge attached thereto. The beam was moved in a vertical direction to cause the tip end of the ball specimen to come into contact with the surface of the disk specimen fixed onto a rotating stage in order to apply a normal load. This test was conducted in an environment in which a lubricant (PAO) was present on the sliding surface by setting the normal load to 0.3 N (a Hertzian contact pressure of about 150 MPa to 250 MPa) and setting a sliding speed to 3.14×10⁻² m/s.

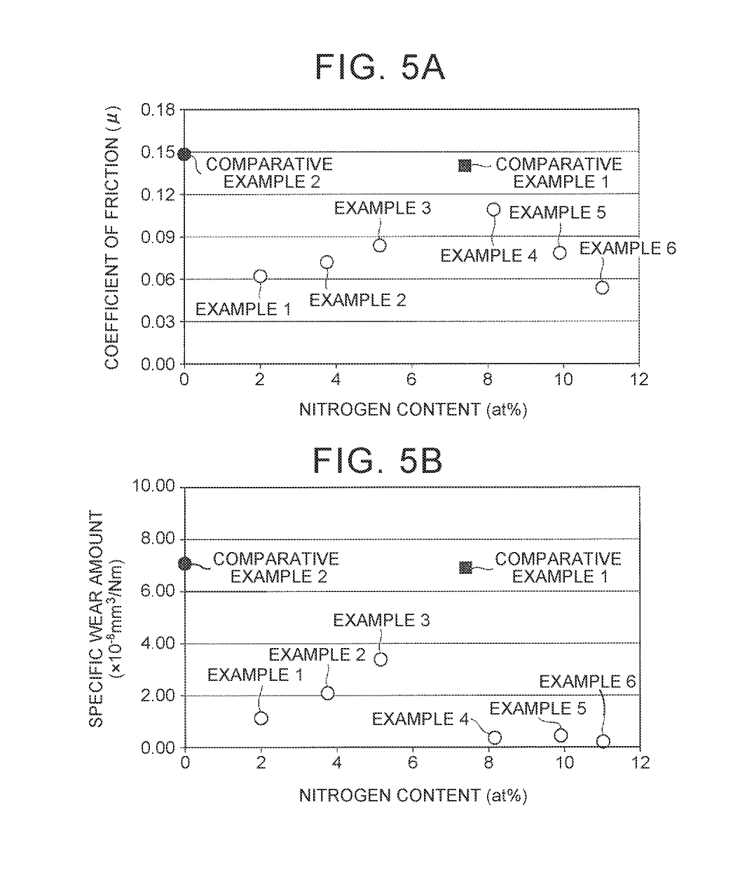

Frictional force at this time was measured by a load cell, and the coefficients of friction of the sliding members (ball specimens) according to Examples 1 to 6 and Comparative Examples 1 and 2 were calculated from a value obtained by dividing the frictional force by the normal load. Furthermore, the specific wear amounts of the sliding members (ball specimens) according to Examples 1 to 6 and Comparative Examples 1 and 2 were measured. The results are shown in FIGS. 5A and 5B and Table 1.

FIG. 5A shows the coefficients of friction of the sliding members (ball specimens) according to Examples 1 to 6 and Comparative Examples 1 and 2 in 3000 cycles of friction. FIG. 5B shows the specific wear amounts of the sliding members (ball specimens) according to Examples 1 to 6 and Comparative Examples 1 and 2 after the ball-on-disk friction and wear test.

[Result 2] As shown in FIGS. 5A and 5B, the coefficients of friction and the specific wear amounts of the sliding members according to Examples 1 to 6 were lower than those of Comparative Examples 1 and 2. In addition, the coefficients of friction and the specific wear amounts of the sliding members according to Examples 1 to 3 had increased in this order. That is, in a case where the nitrogen content was 2 at % to 5 at %, both the coefficient of friction and the specific wear amount had increased as the nitrogen content had increased.

The sliding member according to Example 4 showed the maximum coefficient of friction, and the coefficients of friction of the sliding members of Examples 4 to 6 had decreased in this order. The specific wear amounts thereof were lower than that of any of Examples 1 to 3. That is, in a case where the nitrogen content was 8 at % to 11 at %, the coefficient of friction had a tendency to decrease as the nitrogen content had increased, and the specific wear amount was substantially constant.

From the results, as described in Examples 4 to 6, it can be said that when the nitrogen content of the CNx film is in a range of 2 at % to 11 at %, the coefficient of friction and the specific wear amount of the sliding member decrease. Furthermore, as described in Examples 5 and 6, it can be said that in a case where the nitrogen content of the CNx film is 10 at % to 11 at %, a low coefficient of friction and wear resistance can be compatible with each other.

Ball-on-Disk Friction and Wear Test 2

A ball-on-disk friction and wear test 2 was conducted on the sliding members according to Example 4 and Comparative Examples 1 to 3 in the same method as in the ball-on-disk friction and wear test 1. The difference from the ball-on-disk friction and wear test 1 is that the CNx films and the DLC film corresponding to these examples were formed on not only the ball specimens (sliding members) but also the disk specimens (sliding members).

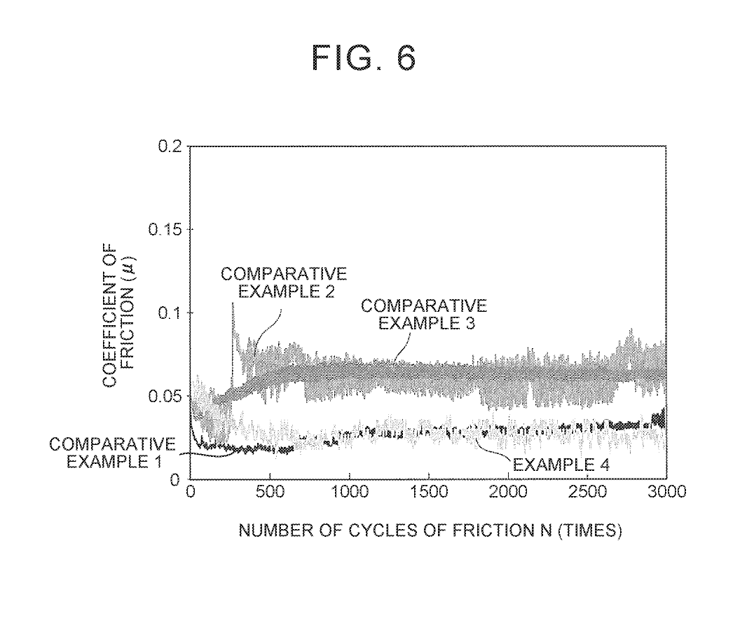

Changes in the coefficients of friction of the sliding members according to Example 4 and Comparative Examples 1 to 3 were measured. The results are shown in FIG. 6. FIG. 6 shows the change in the coefficients of friction of the sliding members according to Example 4 and Comparative Examples 1 to 3.

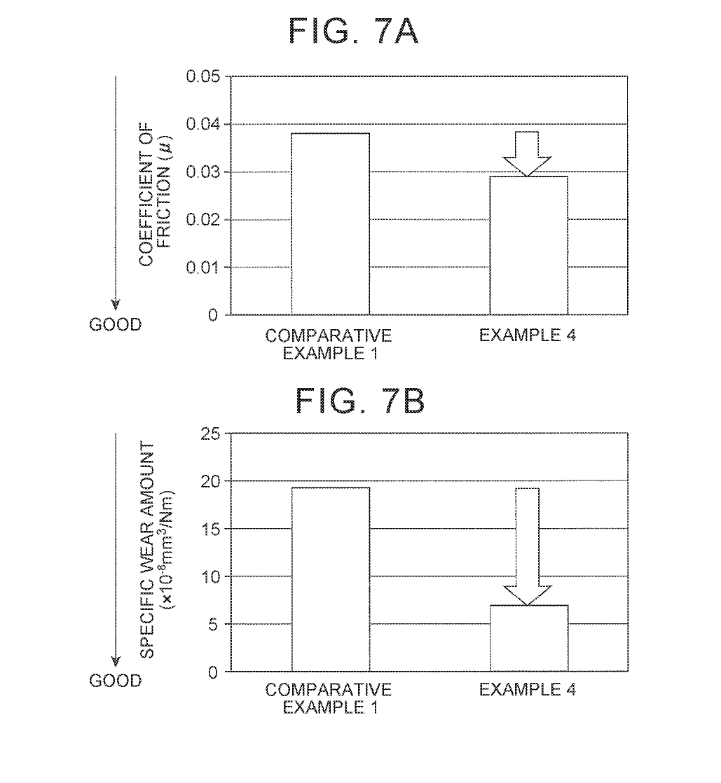

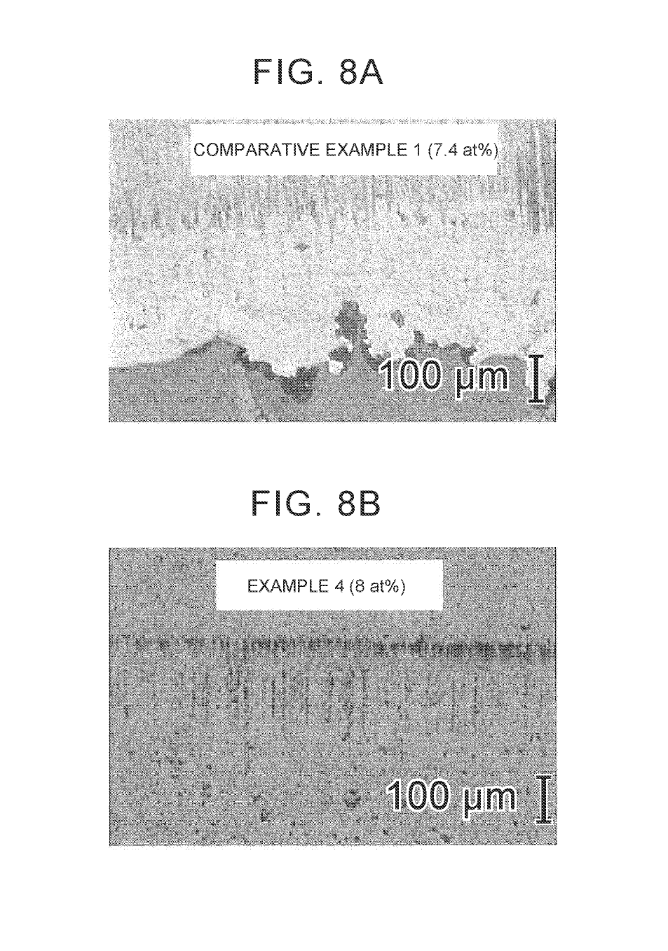

Furthermore, the coefficients of friction and the specific wear amounts of the sliding members according to Comparative Example 1 and Example 4 were measured. The results are shown in FIGS. 7A and 7B. FIG. 7A shows the coefficients of friction of the sliding members (ball specimens) according to Example 4 and Comparative Example 1 in 3000 cycles of friction. FIG. 7B shows the specific wear amounts of the sliding members (ball specimens) according to Example 4 and Comparative Example 1 after the ball-on-disk friction and wear test.

<Surface Observation> The sliding surfaces of the sliding members according to Example 4 and Comparative Example 1 after the ball-on-disk friction and wear test were observed. The results are shown in FIGS. 8A and 8B. FIG. 8A shows the sliding surface of the sliding member (disk specimen) according to Comparative Example 1 after the ball-on-disk friction and wear test, and FIG. 8B shows the sliding surface of the sliding member (disk specimen) according to Example 4 after the ball-on-disk friction and wear test after sliding.

[Result 3] As shown in FIG. 6, the coefficients of friction of the sliding members according to Example 4 and Comparative Example 1 in which the nitrogen-containing amorphous carbon film (CNx film) was formed were lower than those of the sliding members of Comparative Examples 2 and 3 in which the amorphous carbon film (DLC film) that did not contain nitrogen was formed.

In addition, although the coefficient of friction of the sliding member of Example 4 was higher than that of Comparative Example 1 immediately after the start of the test, the coefficient of friction of the sliding member according to Example 4 had decreased with time. In addition, as shown in FIGS. 6 and 7A, the coefficient of friction of the sliding member according to Example 4 was lower than that of Comparative Example 1 in 3000 cycles of friction.

As shown in FIG. 7B, the specific wear amount of the sliding member according to Example 4 was lower than that of Comparative Example 1. As shown in FIG. 8A, the CNx film of the sliding member of Comparative Example 1 worn out at the time of the end of the test. However, as shown in FIG. 8B, the CNx film of the sliding member according to Example 4 had not worn out and was present until the end of the test.

Furthermore, as shown in Table 1, in the ball-on-disk friction and wear test 1, since the CNx film was formed only on the ball specimen according to Example 4, the specific wear amount thereof was 1/20 of that of the DLC film according to Comparative Example 2. However, in the ball-on-disk friction and wear test 2, since the CNx films were formed on both the ball specimen and the disk specimen according to Example 4, the specific wear amount thereof was 1/100 of that of the DLC film according to Comparative Example 2 in Table 1.

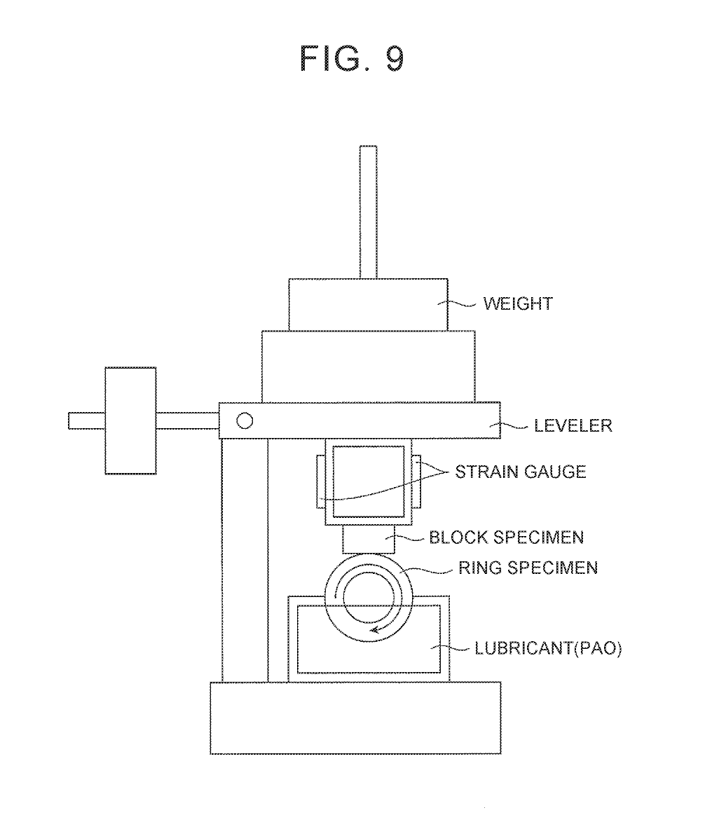

Block-on-Ring Friction and Wear Test A block-on-ring friction and wear test was conducted by using a tester illustrated in FIG. 9. Block specimens as the sliding members according to Example 4 and Comparative Example 2 were prepared. As illustrated in FIG. 9, a ring specimen (SUJ 2 in JIS standards) was prepared, a block specimen was disposed thereon, and a normal load was applied to the block specimen on the circumferential surface of the ring specimen along the vertical direction by a weight via a leveler.

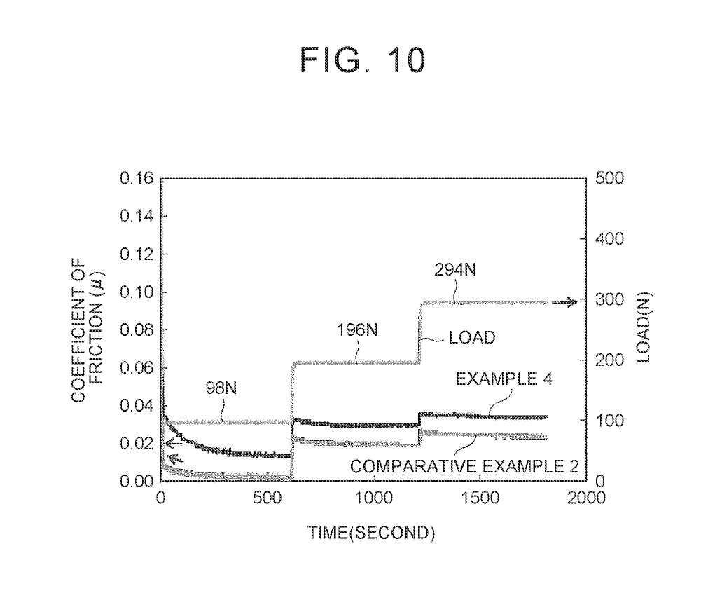

In this state, a portion of the ring specimen was immersed into a lubricant (a base oil (PAO) used in an engine oil), and while rotating the ring specimen, the ring specimen was allowed to slide on the block specimen. The coefficient of friction was measured while a normal load is changed between 98 N and 294 N using a strain gauge (while increasing the load to 98 N, 196 N, and 294 N in stages) and rotating the ring specimen at a sliding speed of 160 rpm. The results are shown in FIG. 10. FIG. 10 shows changes in the coefficients of friction of the sliding members (block specimens) according to Example 4 and Comparative Example 2 according to a change in the normal load.

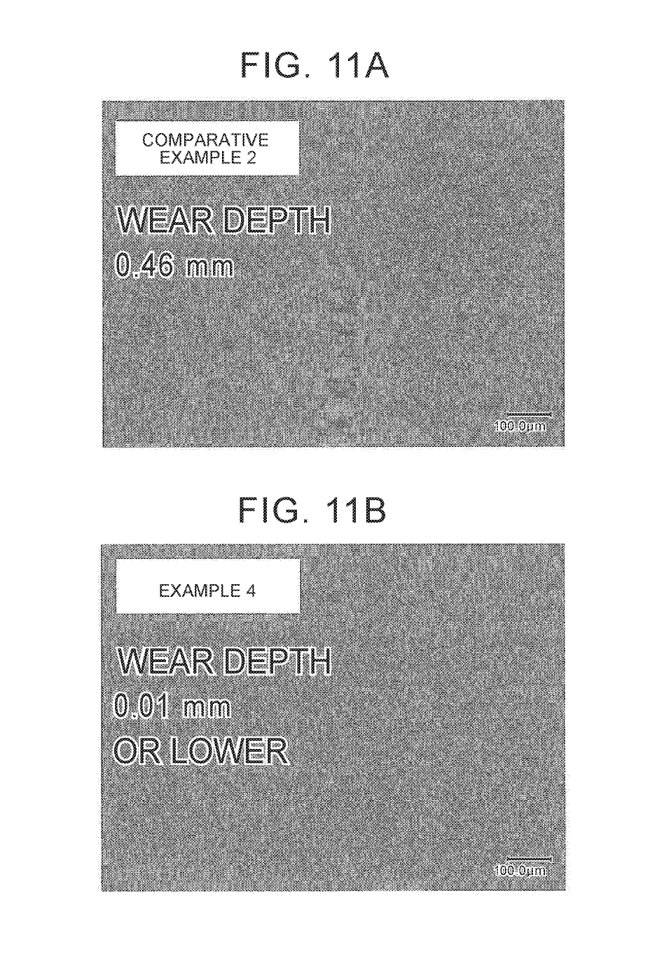

The surfaces of the sliding members according to Example 4 and Comparative Example 2 after the block-on-ring friction and wear test were observed with a microscope. The results are shown in FIGS. 11A and 11B. FIG. 11A shows the sliding surface of the sliding member (block specimen) according to Comparative Example 2 after the block-on-ring friction and wear test, and FIG. 11B shows the sliding surface of the sliding member (block specimen) according to Example 4 after the block-on-ring friction and wear test.

[Result 4] The sliding member according to Example 4 was a sliding member having the highest coefficient of friction among the other Examples as described in Result 2. However, regardless of this, the coefficient of friction thereof was lower than that of Comparative Example 2 under any load. In addition, as is apparent from FIGS. 11A and 11B, the wear amount (wear depth) of the sliding member according to Example 4 was lower than that of Comparative Example 2. It is thought that this is for the reasons described above with reference to FIGS. 2A and 2B.

Particularly, since the CNx film of the sliding member according to Example 4 did not contain hydrogen unlike the DLC film of the sliding member according to Comparative Example 2, it can be said that the hardness thereof was high, the density of dangling bonds (broken bonds) was high, and responsiveness to additives and the like in the lubricant was excellent.

While the embodiment of the invention has been described in detail, specific configurations are not limited to this embodiment and Examples, and changes in design are included in the invention without departing from the gist of the invention. In addition, the sliding member of the invention can be used as an engine component in a vehicle and a driving system component such as a transmission.

What is claimed is:

1. A production method of a sliding member which is capable of moving relative to a counterpart and includes a nitrogen-containing amorphous carbon film formed on a surface of a substrate, allows a surface of the amorphous carbon film to act as a sliding surface, and is used in an environment in which a lubricant is present on the sliding surface, the method comprising:
forming the nitrogen-containing amorphous carbon film on the substrate by causing carbon to be deposited on the surface of the substrate through a filtered arc deposition method while emitting a nitrogen ion beam toward the surface of the substrate so as to cause a nitrogen content of the amorphous carbon film to be 2 at % to 11 at %.

2. The production method according to claim 1, wherein the forming of the amorphous carbon film is performed so as to cause the nitrogen content to be 10 at % to 11 at %.

3. A sliding member which is capable of moving relative to a counterpart, comprising:
a substrate; and
an amorphous carbon film which is provided on the substrate, and has a nitrogen content of 2 at % to 11 at % and a surface hardness in a range of 25 GPa to 80 GPa.

4. The member according to claim 3, wherein the nitrogen content is 10 at % to 11 at %.
